(19) United States
(12) Patent Application Publication
(10) Pub. No.: US 2015/0054524 A1
(43) Pub. Date: Feb. 26, 2015

(54) Partial Discharge Measurement Device and Method

(71) Applicant: Hitachi, Ltd., Tokyo (JP)

(72) Inventors: Chie KOBAYASHI, Tokyo (JP); Toshiaki ROKUNOHE, Tokyo (JP); Yoshiharu WADA, Tokyo (JP); Go KOBAYASHI, Tokyo (JP); Ken OBAYASHI, Tokyo (JP)

(21) Appl. No.: 14/451,141

(22) Filed: Aug. 4, 2014

(30) Foreign Application Priority Data
Aug. 22, 2013 (JP) 2013-171853

(51) Int. Cl. G01R 31/12; G01R 31/14; G01R 31/40

(52) U.S. Cl. CPC G01R 31/1227; G01R 31/40; G01R 31/14
USPC 324/551

(57) ABSTRACT

A partial discharge measurement device according to the present invention includes a frequency separation unit for separating a partial discharge signal which occurs in an apparatus under diagnosis and is detected by a sensor into the partial discharge signal and a main circuit voltage phase signal, an arithmetic device which receives the partial discharge signal and the main circuit voltage phase signal separated by the frequency separation unit and calculates a partial discharge signal synchronized with a main circuit voltage based on the partial discharge signal and the main circuit voltage phase signal, a power supply device for extracting a voltage obtained by dividing the main circuit voltage and supplying a power supply voltage to the arithmetic device, and a control unit for issuing an instruction for powering on or off at least the arithmetic device to the power supply device.

### CLAIM OF PRIORITY

The present application claims priority from Japanese Patent application serial no. 2013-171853, filed on Aug. 22, 2013, the content of which is hereby incorporated by reference into this application.

### FIELD OF THE INVENTION

The present invention relates to a partial discharge measurement device and a method thereof, and for example, relates to a partial discharge measurement device and a method thereof suitable for detecting abnormality or degradation of an electric insulation unit of a power apparatus by measuring partial discharge in the power apparatus.

### BACKGROUND OF THE INVENTION

To detect abnormality or degradation of an electric insulation unit of a power apparatus, the occurrence of partial discharge in the electric insulation unit is detected under voltage application, and the location and extent of insulation failure is determined from the combined result of the detected discharge electric charge amount, occurrence frequency, and occurrence phase. Further, to examine a partial discharge occurrence phase under voltage application, it is necessary to acquire the phase information of the applied voltage.

However, the occurrence phase, the discharge electric charge amount, and the occurrence frequency cannot be measured with the same detection method, depending on the type of sensor and measurement instrument. In such a case, individual detection is required. Further, due to the constraints of the configuration of the apparatus and the type of sensor, it might be difficult to detect the partial discharge and the voltage phase in the same part of the apparatus.

Accordingly, in most cases, the voltage phase information is transferred through an electric wire connected between voltage phase measurement means provided at a voltage phase information detection point and a partial discharge measurement device.

Accordingly, in the case of a great distance between the voltage phase information detection point and the partial discharge measurement device, the installation of the electric wire for connection therebetween requires extensive work, which makes it difficult to install the electric wire. Further, in some cases, it is impossible to install the electric wire.

Accordingly, e.g., Japanese Unexamined Patent Publication No. Hei 6-11534 (Patent Document 1) describes means for transferring voltage phase information by wireless without installing an electric wire. In the means described in Patent Document 1, it is not necessary to install the electric wire; however, there is a problem that a phase information transmitter and a receiver of a partial discharge measurement device need to be located within the reach of radio waves and measurement is difficult e.g. in areas of high electromagnetic noise. Further, there is a problem that the voltage phase information has to be transmitted in real time.

To solve these problems, e.g., Japanese Unexamined Patent Publication No. 2001-183411 (Patent Document 2) describes a partial discharge measurement system including a device for detecting and storing only zero crossing times of an AC voltage.

More specifically, the partial discharge measurement system described in Patent Document 2 includes intensity information detection means for detecting intensity information of partial discharge in a power apparatus, first timer means for obtaining first time information corresponding to a time of detection of the intensity information detected by the intensity information detection means, first storage means for storing the intensity information and the first time information, voltage phase information detection means for detecting voltage phase information of the power apparatus, second timer means for obtaining second time information corresponding to a time of detection of the voltage phase information of the power apparatus detected by the voltage phase information detection means, second storage means for storing the voltage phase information and the second time information, and detection means for obtaining a relationship between the intensity information and the voltage phase information at a predetermined time based on the first time information and the second time information and detecting insulation abnormality of the power apparatus based on the obtained relationship between the intensity information and the voltage phase information.

However, in the partial discharge measurement system described in Patent Document 2, it is necessary to lay a cable from a power supply facility to operate the system, which requires electric work and therefore makes it difficult to easily install the device. Further, a surge voltage enters from the power line, which requires filters or the like to prevent it, and therefore disadvantageously increases the size of the device.

To solve these problems, e.g., Japanese Unexamined Patent Publication No. 2003-284252 (Patent Document 3) describes a power supply device for a measurement device in a transmission and distribution system which extracts power from a transmission and distribution line with a voltage even in a state where a current does not flow through the transmission and distribution line, without requiring a high-voltage insulation measure, and supplies power to the measurement device in the transmission and distribution system.

More specifically, the power supply device for the measurement device in the transmission and distribution system described in Patent Document 3 which stores power obtained by a capacitor circuit formed by mounting a spatial electrode around the transmission and distribution line and including spatial capacitance with the transmission and distribution line and the ground and intermittently outputs a voltage to the measurement device includes a protection circuit for suppressing an overvoltage by converting a voltage obtained by the spatial electrode into an appropriate voltage, a rectifier circuit for converting the voltage outputted from the protection circuit from AC to DC, a charging battery for storing electricity outputted from the rectifier circuit, a voltage detector for detecting the voltage of the charging battery, and a voltage generator for intermittently outputting a voltage necessary for the load of the measurement device from the voltage detected by the voltage detector.

However, while Patent Document 3 describes the technique in which the power supply device for the measurement device in the transmission and distribution system extracts power from the transmission and distribution line and supplies power to the measurement device in the transmission and distribution system, there is a problem that the amount of charge is small so that power necessary to transmit data cannot be obtained.

To solve such a problem, e.g., Japanese Unexamined Patent Publication No. 2008-256550 (Patent Document 4) describes a capacitor voltage division type partial discharge detection device, for detecting partial discharge occurred inside a gas insulated switch gear, which can supply power necessary to drive the device, regardless of an external main power supply.

More specifically, the partial discharge detection device of the gas insulated switch gear described in Patent Document 4, for detecting partial discharge occurred inside the gas insulated switch gear including a gas insulated container which is filled with insulating gas and grounded and a central conductor which extends in the longitudinal direction inside the gas insulated container and is supported by an insulating spacer for partitioning the gas insulated container and to which a main circuit voltage is applied, includes a capacitor voltage division type voltage detector for, by using a floating electrode provided between the gas insulated container and the central conductor, detecting a signal obtained by superimposing the main circuit voltage signal on an electromagnetic wave signal caused by partial discharge occurred in the gas insulated container, as a divided voltage occurred on the floating electrode, a signal separation unit for separating a partial discharge signal and a main circuit voltage phase signal from the voltage detected by the capacitor voltage division type voltage detector, an arithmetic unit for calculating a partial discharge signal synchronized with the main circuit voltage based on the partial discharge signal and the main circuit voltage phase signal separated by the signal separation unit, and an internal power supply unit for generating a power supply voltage for driving the signal separation unit and the arithmetic unit by extracting a voltage obtained by dividing the main circuit voltage from the voltage detected by the capacitor voltage division type voltage detector.

However, while Patent Document 4 describes the partial discharge detection device of the gas insulated switch gear which can supply power necessary to drive the device regardless of the external main power supply, this device for detecting partial discharge has a configuration for always operating the partial discharge measurement instrument without a device for charging the power supply for supplying power necessary to drive the device, which leads to an insufficient amount of power to transmit data. Further, since the sensor for detecting partial discharge and the sensor for feeding power are the same capacitor voltage division type voltage detector, a very large sensor is required to obtain enough power to operate the partial discharge detection device of the power apparatus, which disadvantageously increases the size of the device.

The present invention has been made in view of the foregoing, and it is an object of the present invention to provide a partial discharge measurement device and a method thereof that can supply power necessary to drive a device regardless of an external main power supply, obtain enough power to transmit data, and obtain enough power to operate the partial discharge detection device of a power apparatus without increasing the size of the device.

### SUMMARY OF THE INVENTION

To achieve the above object, a partial discharge measurement device according to the present invention includes a frequency separation unit for separating a partial discharge signal which occurs in an apparatus under diagnosis and is detected by a sensor into the partial discharge signal and a main circuit voltage phase signal, an arithmetic device which receives the partial discharge signal and the main circuit voltage phase signal separated by the frequency separation unit and calculates a partial discharge signal synchronized with a main circuit voltage based on the partial discharge signal and the main circuit voltage phase signal, a power supply device for extracting a voltage obtained by dividing the main circuit voltage and supplying a power supply voltage to the arithmetic device, and a control unit for issuing an instruction for powering on or off at least the arithmetic device to the power supply device.

Further, to achieve the above object, a partial discharge measurement device according to the present invention includes a frequency separation unit which includes a high-pass filter for removing a commercial frequency component from a partial discharge signal which occurs in an apparatus under diagnosis and is detected by a sensor and a low-pass filter for extracting the commercial frequency component and separates the partial discharge signal into a partial discharge signal and a main circuit voltage phase signal, an arithmetic device which receives the partial discharge signal and the main circuit voltage phase signal separated by the frequency separation unit and calculates a partial discharge signal synchronized with a main circuit voltage based on the partial discharge signal and the main circuit voltage phase signal, a power supply device which includes a rectifier device, a charging device, and a DC/DC converter, extracts a voltage obtained by dividing the main circuit voltage of the commercial frequency from the low-pass filter, and supplies a power supply voltage to the arithmetic device, and a control unit for issuing an instruction for powering on or off at least the arithmetic device to the power supply device.

Further, to achieve the above object, a partial discharge measurement method according to the present invention includes the steps of removing by a high-pass filter a commercial frequency component from a partial discharge signal which occurs in an apparatus under diagnosis and is detected by a sensor and extracting by a low-pass filter the commercial frequency component, thus separating the partial discharge signal into a partial discharge signal and a main circuit voltage phase signal, receiving the separated partial discharge signal and the main circuit voltage phase signal and calculating by an arithmetic device a partial discharge signal synchronized with a main circuit voltage based on the partial discharge signal and the main circuit voltage phase signal, extracting a voltage obtained by dividing the main circuit voltage of the commercial frequency from the low-pass filter and supplying a power supply voltage to the arithmetic device by a power supply device including a rectifier device, a charging device, and a DC/DC converter, and issuing by a control unit an instruction for powering on or off at least the arithmetic device to the power supply device.

According to the present invention, it is possible to supply power necessary to drive the device regardless of an external main power supply, obtain enough power to transmit data, and obtain enough power to operate the partial discharge detection device of a power apparatus without increasing the size of the device.

### BRIEF DESCRIPTION OF THE DRAWINGS

FIG. 1 is a schematic block diagram showing a partial discharge measurement device according to a first embodiment of the present invention;

FIG. 2 is a schematic block diagram showing a partial discharge measurement device according to a second embodiment of the present invention;

FIG. 3 is a schematic block diagram showing a partial discharge measurement device according to a third embodiment of the present invention;

FIG. 4 is a schematic block diagram showing a partial discharge measurement device according to a fourth embodiment of the present invention; and

FIG. 5 is a diagram for explaining a procedure for partial discharge diagnosis using the partial discharge measurement device according to the present invention.

### DESCRIPTION OF THE PREFERRED EMBODIMENTS

Hereinafter, a partial discharge measurement device and a partial discharge measurement method according to the present invention will be described based on illustrated embodiments. In the embodiments, the same components are denoted by the same reference numerals.

### First Embodiment

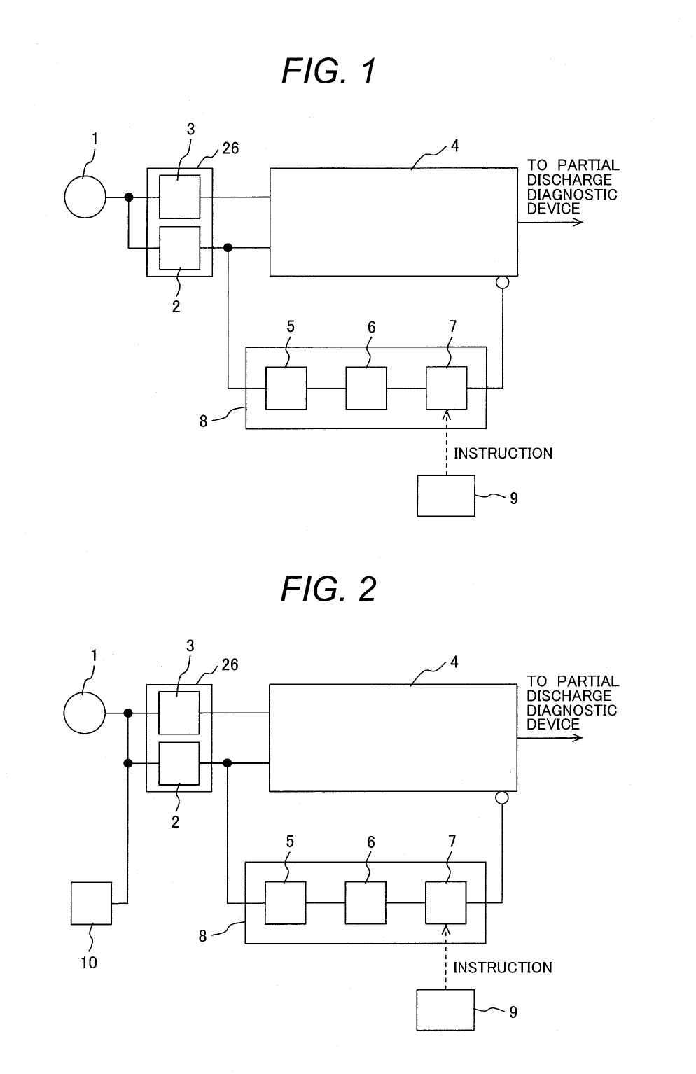

FIG. 1 shows a partial discharge measurement device according to the first embodiment of the present invention. As shown in FIG. 1, the partial discharge measurement device according to this embodiment is substantially composed of a frequency separation unit 26 which is composed of a high-pass filter 3 for removing a commercial frequency component from a partial discharge signal which occurs in an apparatus under diagnosis (e.g., gas insulated apparatus) and is detected by a sensor 1 and a low-pass filter 2 for extracting the commercial frequency component and separates the partial discharge signal into a partial discharge signal and a main circuit voltage phase signal, an arithmetic device 4 which receives the partial discharge signal and the main circuit voltage phase signal separated by the frequency separation unit 26 and calculates a partial discharge signal synchronized with a main circuit voltage based on the partial discharge signal and the main circuit voltage phase signal, a power supply device 8 which is composed of a rectifier device 5, a charging device (e.g., battery) 6, and a DC/DC converter 7, extracts a voltage obtained by dividing the main circuit voltage of the commercial frequency from the low-pass filter 2, and supplies a power supply voltage to the arithmetic device 4, and a control unit 9 for issuing an instruction for powering on or off the arithmetic device 4 to the DC/DC converter 7 in the power supply device 8.

That is, in the partial discharge measurement device according to this embodiment, as shown in FIG. 1, the partial discharge signal which has occurred in the power apparatus (e.g., gas insulated apparatus) is detected by the sensor 1 and separated into the partial discharge signal and the main circuit voltage phase signal by the high-pass filter 3 for removing the commercial frequency component and the low-pass filter 2 for extracting the commercial frequency component. The separated partial discharge signal and main circuit voltage phase signal are inputted to the arithmetic device 4 which calculates the partial discharge signal synchronized with the main circuit voltage based on the separated partial discharge signal and main circuit voltage phase signal.

Further, the voltage obtained by dividing the main circuit voltage of the commercial frequency extracted by the low-pass filter 2 from the partial discharge signal detected by the sensor 1 is extracted, and converted by the rectifier device 5 in the power supply device 8 into a DC voltage for charging the charging device 6 (this state is called a charge mode).

Further, the control unit 9 provides a monitor mode instruction to turn on the DC/DC converter 7 and power on the arithmetic device 4 to start partial discharge measurement.

Methods of instructions by the control unit 9 include a method of an instruction to start monitoring periodically with a timer (a method of performing on/off control with a timer, e.g., issuing an instruction for turning on the DC/DC converter 7 to make a measurement every eight hours, and issuing an instruction for turning off the DC/DC converter 7 to switch to the charge mode except during the measurement) and a method of receiving an external signal and sending an instruction in accordance therewith (a method of having a receiver in the control unit 9 and turning on or off the DC/DC converter 7 in accordance with an external instruction).

Further, in the partial discharge measurement device according to this embodiment, the frequency separation unit 26, the arithmetic device 4, the power supply device 8, and the control unit 9 are formed in one and can be connected to the sensor 1 with a single motion through a connection device such as a connector.

In the conventional partial discharge measurement device, a cable of more than several m is connected between the sensor and the arithmetic device; accordingly, matching resistors are needed at both ends of the cable. Further, since the capacitance between the sensor and the power apparatus is on the order of pF, the impedance is on the order of GΩ at the commercial frequency, and a voltage induced by the connection of the matching resistor of 50 or 75Ω is determined by the voltage division ratio and therefore becomes almost zero. For this reason, the signal of only the partial discharge signal is detected.

On the other hand, in the partial discharge measurement device according to this embodiment, the frequency separation unit 26, the arithmetic device 4, the power supply device 8, and the control unit 9 are formed in one and can be connected to the sensor 1 with a single motion through the connection device such as a connector, which shortens the distance between the sensor 1 and the power apparatus 4 and reduces the size of the device incorporating the low-pass filter 2 and the high-pass filter 3 for detecting the partial discharge signal.

Further, the power from the sensor 1 is converted into a desired voltage by the rectifier circuit, and fed to the load of the arithmetic device 4. The sensor 1 is a sensor capable of detecting partial discharge such as a dipole antenna.

With the configuration of this embodiment, it is possible to supply power necessary to drive the device regardless of an external main power supply, obtain enough power to transmit data, and obtain enough power to operate the partial discharge detection device of the power apparatus without increasing the size of the device. That is, by providing the charging device 6 and the DC/DC converter 7 in the power supply device 8 and having the control unit 9, it is possible to increase the power supply capability and perform charging and monitoring with efficiency. Further, the increased power supply amount advantageously enables wireless communication.

### Second Embodiment

FIG. 2 shows a partial discharge measurement device according to the second embodiment of the present invention. The partial discharge measurement device according to this embodiment shown in FIG. 2 is characterized in that a feed unit 10 for extracting power from a high-voltage apparatus (e.g., gas insulated apparatus) is connected before the frequency separation unit 26. That is, this embodiment has a configuration for increasing the feed amount by not only feeding power from the sensor 1 but also providing the feed unit 10 for extracting power from the high-voltage apparatus. The other configuration is the same as that of the first embodiment.

Further, in this embodiment, as shown in FIG. 2, a source voltage is extracted from the feed unit 10 and sent to the power supply device 8, and voltage phase information extracted from the feed unit 10 is sent to the arithmetic device 4.

Further, a plurality of feed units 10 may be provided. Methods of feed by the feed unit 10 include feed using a spatial electrode, feed using sunlight, and feed using a coil.

With the configuration of this embodiment, it is possible to obtain advantages similar to those of the first embodiment and also possible to increase the feed amount, and negate the need for a power line by using a plurality of feed units 10. Further, by providing the feed unit 10 for extracting power from the high-voltage apparatus, it is not necessary to lay a cable from a power supply facility and conduct electric work, which advantageously makes it possible to easily install the device.

### Third Embodiment

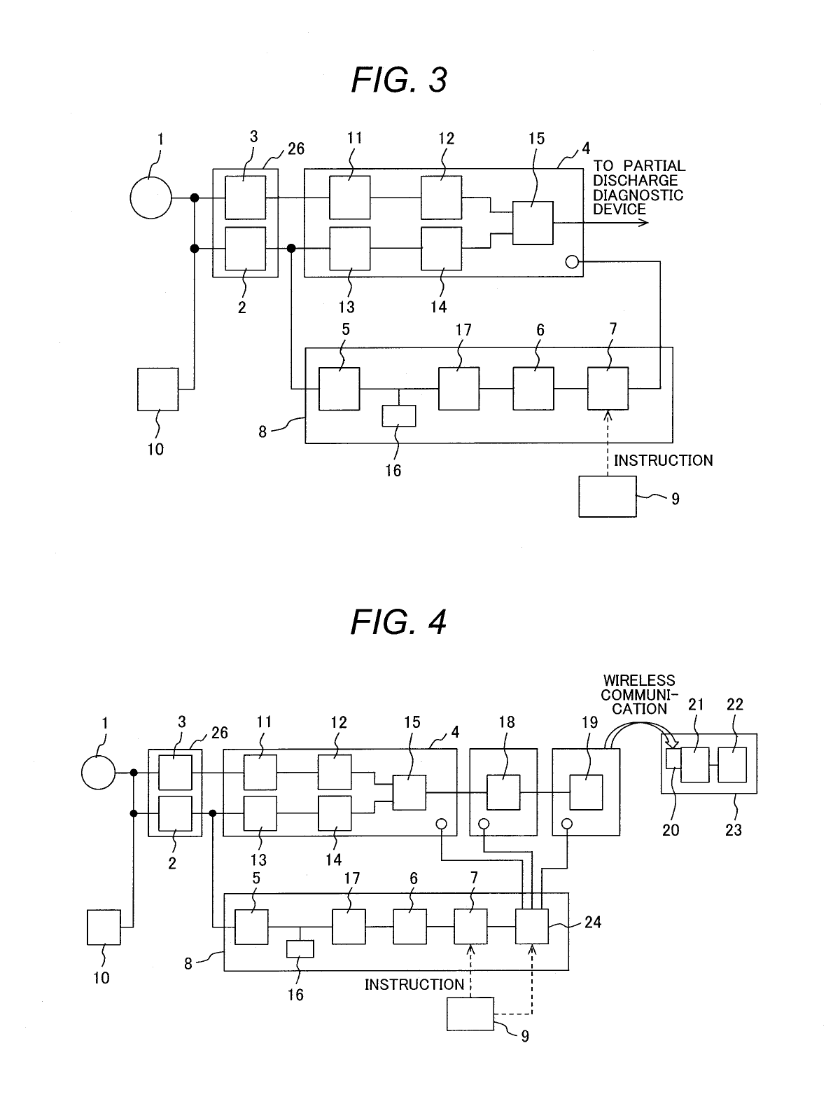

FIG. 3 shows a partial discharge measurement device according to the third embodiment of the present invention. In the partial discharge measurement device according to this embodiment shown in FIG. 3, the arithmetic device 4 is composed of a detector circuit 11 for detecting, at given time intervals, only the maximum value and the minimum value of the partial discharge signal that has passed through the high-pass filter 3, an A/D converter 12 for performing A/D conversion on the signal detected by the detector circuit 11, a signal processing device 15 for time-synchronizing the signal that has passed through the A/D converter 12 with voltage phase information, a phase adjustment circuit 13 for adjusting the phase shift of the partial discharge signal that has passed through the low-pass filter 2, a waveform adjustment circuit 14 for detecting the zero crossing of the signal whose phase shift has been adjusted by the phase adjustment circuit 13 and sending only the zero cross signal to the signal processing device 15. On the other hand, the power supply device 8 is composed of a capacitor 16 for storing a voltage rectified by the rectifier device 5 and a second DC/DC converter 17 which turns on if the voltage stored by the capacitor 16 exceeds a given voltage, and charges the charging device 6. The other configuration is the same as that of the second embodiment.

In this embodiment, as shown in FIG. 3, only the maximum value and the minimum value of the partial discharge signal that has passed through the high-pass filter 3 are detected at fixed time intervals by the detector circuit 11. This can reduce the amount of information of high-frequency signals in a several GHz band. Further, the detected signal is sent to the A/D converter 12 which converts it into the digital value, thereby further reducing the amount of data. Since the amount of data is reduced in advance in the detector circuit 11, a general A/D converter in a band of several kHz to several hundred MHz can be used as the A/D converter 12. The signal that has passed through the A/D converter 12 is sent to the signal processing device 15 and time-synchronized with the voltage phase information. Further, as to the voltage phase information inputted to the low-pass filter 2, the phase shift is adjusted by the phase adjustment circuit 13, and the zero crossing is detected by the waveform adjustment circuit 14. Only the zero cross signal is sent to the signal processing device 15 and time-synchronized with the partial discharge signal.

Further, in the power supply device 8, the capacitor 16 stores the voltage rectified by the rectifier device 5, and only if the voltage stored by the capacitor 16 exceeds the given voltage, the second DC/DC converter 17 turns on and charges the charging device 6. The charging device 6 is, for example, a battery.

With the configuration of this embodiment, it is possible to obtain advantages similar to those of the second embodiment. In addition, the phase of the commercial frequency voltage signal obtained through the low-pass filter 2 is adjusted to the voltage phase of the power apparatus by the phase adjustment circuit 13, and the signal is converted by the waveform adjustment circuit 14 into a trigger signal which can be used as a trigger signal for the A/D converter 12. Further, by converting the partial discharge analog signal obtained through the high-pass filter 3 and the low-pass filter 2 into the digital value and a communication signal by the A/D converter 12, the partial discharge signal can be sent to a partial discharge diagnostic device. Furthermore, power can be extracted from a high-voltage conductor and continuously supplied to the measurement device, which can advantageously negate the need for the power line by using a plurality of feed units 10, batteries, or the like.

### Fourth Embodiment

FIG. 4 shows a partial discharge measurement device according to the fourth embodiment of the present invention. In the example of the partial discharge measurement device according to this embodiment shown in FIG. 4, a signal processed by the arithmetic device 4 is transmitted by wireless.

More specifically, the partial discharge measurement device according to this embodiment is composed of a memory 18 for storing the partial discharge signal processed by the arithmetic device 4, a wireless transmitter 19 for transmitting the partial discharge signal stored in the memory 18, a wireless receiver 20 which is installed at a location distant from the wireless transmitter 19 and receives the signal from the wireless transmitter 19, a diagnostic device 23 for performing defect determination from the signal received by the wireless receiver 20, and a switch 24 for powering on or off the arithmetic device 4, the memory 18, and the wireless transmitter 19 based on an instruction from the control unit 9. Further, the diagnostic device 23 includes a partial discharge diagnostic unit 21 for performing defect determination based on the signal received by the wireless receiver 20 and a display unit 22 for performing guidance display color-coded in e.g. red, blue, and yellow in accordance with the result of the diagnosis by the partial discharge diagnostic unit 21.

In this embodiment, as shown in FIG. 4, the memory 18 stores the partial discharge signal processed by the arithmetic device 4, and the wireless transmitter 19 transmits it to the wireless receiver 20 installed at a distant location. The signal received by the wireless receiver 20 is sent to the partial discharge diagnostic unit 21 which determines a defect type. At this time, for power required for signal transmission by the wireless transmitter 19, power inputs are switched through the switch 24, which enables efficient power consumption.

At this time, first, the control unit 9 issues an instruction for turning on the DC/DC converter 7. Then, the control unit 9 issues to the switch 24 an instruction for powering on only the arithmetic device 4 and the memory 18. Lastly, the arithmetic device 4 is turned off, and only the memory 18 and the wireless transmitter 19 are turned on. After the completion of measurement and data transmission, the mode is switched to the charge mode to charge the capacitor 16 and the charging device 6.

To efficiently suppress the power consumption of the arithmetic device 4, the memory 18, and the wireless transmitter 19 in partial discharge measurement, (A) first, the control unit 9 issues an instruction for turning on the DC/DC converter 7. (B) Then, the control unit 9 issues to the switch 24 an instruction for turning on only the arithmetic device 4 and the memory 18, for partial discharge calculation, and the result is stored in the memory 18. (C) Then, only the memory 18 and the wireless transmitter 19 are turned on with the switch 24, and the result stored in the memory 18 is transmitted by the wireless transmitter 19 to the diagnostic device 23. (D) Lastly, the switch 24 and the DC/DC converter 7 are turned on, and the mode is switched to the charge mode (the charge mode period may be provided between (B) and (C)). Since the power consumption of the control unit 9 is small, the control unit 9 is connected to the charging device (e.g., battery) 6 and operated.

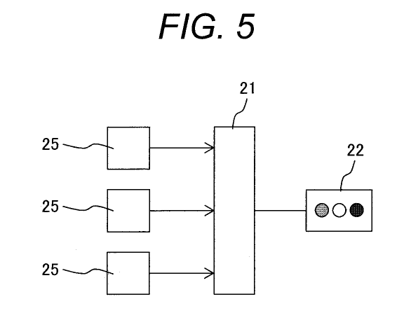

Next, a procedure for partial discharge diagnosis using the partial discharge measurement device 25 according to this embodiment will be described with reference to FIG. 5.

As shown in FIG. 5, signals from the partial discharge measurement devices 25 installed at various positions of the power apparatus are sent to the partial discharge diagnostic unit 21. The partial discharge diagnostic unit 21 performs (1) synchronization among measurement start times of the partial discharge measurement devices 25, (2) defect type determination, (3) position evaluation, (4) defect size estimation, and (5) breakdown voltage estimation, thereby performing risk assessment of the power apparatus. The display unit 22 performs guidance display color-coded in e.g. red, blue, and yellow in accordance with the result of the risk assessment.

When the display unit 22 performs guidance display color-coded in red, blue, and yellow, for example, the red color indicates “abnormal”, the blue color indicates “not abnormal”, and the yellow color indicates “not abnormal but necessary to monitor the state”.

With the configuration of this embodiment, it is possible to obtain advantages similar to those of the third embodiment. In addition, since a wireless communication unit composed of the wireless transmitter 19 and the wireless receiver 20 is added, it is possible to collect the partial discharge signal without a cable, and the use of the switch 24 negates the need for the power line. Further, by transmitting the partial discharge signal containing phase information digitized by the A/D converter 12, it is possible to easily collect signals from multiple sensors, which can greatly reduce the labor required for diagnosis. Furthermore, the display unit 22 displays the result of the risk assessment of the power apparatus, which can advantageously make it possible to determine the state of the power apparatus at a glance.

The present invention is not limited to the above embodiments, but includes various modifications. For example, the above embodiments have been described in detail for ease of description of the present invention, and are not necessarily limited to those having all the described configurations. Further, it is possible to substitute a configuration of one embodiment for a part of the configuration of another embodiment, and it is also possible to add a configuration of one embodiment to the configuration of another embodiment. Furthermore, for a part of the configuration of each embodiment, it is possible to add, delete, and substitute another configuration.

### [Reference Numerals]

1: sensor
2: low-pass filter
3: high-pass filter
4: arithmetic device
5: rectifier device
6: charging device
7: DC/DC converter
8: power supply device
9: control unit
10: feed unit
11: detector circuit
12: A/D converter
13: phase adjustment circuit
14: waveform adjustment circuit
15: signal processing device
16: capacitor
17: second DC/DC converter
18: memory
19: wireless transmitter
20: wireless receiver
21: partial discharge diagnostic unit
22: display unit
23: diagnostic device
24: switch
25: partial discharge measurement device
26: frequency separation unit

What is claimed is:

1. A partial discharge measurement device comprising:
a frequency separation unit for separating a partial discharge signal which occurs in an apparatus under diagnosis and is detected by a sensor into the partial discharge signal and a main circuit voltage phase signal;
an arithmetic device which receives the partial discharge signal and the main circuit voltage phase signal separated by the frequency separation unit and calculates a partial discharge signal synchronized with a main circuit voltage based on the partial discharge signal and the main circuit voltage phase signal;
a power supply device for extracting a voltage obtained by dividing the main circuit voltage and supplying a power supply voltage to the arithmetic device; and
a control unit for issuing an instruction for powering on or off at least the arithmetic device to the power supply device.

2. A partial discharge measurement device comprising:
a frequency separation unit which includes a high-pass filter for removing a commercial frequency component from a partial discharge signal which occurs in an apparatus under diagnosis and is detected by a sensor and a low-pass filter for extracting the commercial frequency component and separates the partial discharge signal into a partial discharge signal and a main circuit voltage phase signal;
an arithmetic device which receives the partial discharge signal and the main circuit voltage phase signal separated by the frequency separation unit and calculates a partial discharge signal synchronized with a main circuit voltage based on the partial discharge signal and the main circuit voltage phase signal;
a power supply device which includes a rectifier device, a charging device, and a DC/DC converter, extracts a voltage obtained by dividing the main circuit voltage of the commercial frequency from the low-pass filter, and supplies a power supply voltage to the arithmetic device; and
a control unit for issuing an instruction for powering on or off at least the arithmetic device to the power supply device.

3. The partial discharge measurement device according to claim 2, wherein the voltage extracted by dividing the main circuit voltage of the commercial frequency from the low-pass filter is converted by the rectifier device into a DC voltage for charging the charging device.

4. The partial discharge measurement device according to claim 2, wherein upon receiving a monitor mode instruction from the control unit, the power supply device turns on the DC/DC converter to power on the arithmetic device.

5. The partial discharge measurement device according to claim 1, wherein a feed unit is connected before the frequency separation unit.

6. The partial discharge measurement device according to claim 2,
wherein the arithmetic device includes a detector circuit for detecting, at given time intervals, only a maximum value and a minimum value of a partial discharge signal that has passed through the high-pass filter, an A/D converter for performing A/D conversion on a signal detected by the detector circuit, a signal processing device for time-synchronizing a signal that has passed through the A/D converter with voltage phase information, a phase adjustment circuit for adjusting a phase shift of a partial discharge signal that has passed through the low-pass filter, and a waveform adjustment circuit for detecting zero crossing of a signal whose phase shift has been adjusted by the phase adjustment circuit and sending only a zero cross signal to the signal processing device, and
wherein the power supply device includes a capacitor for storing a voltage rectified by the rectifier device, and a second DC/DC converter which turns on if the voltage stored by the capacitor exceeds a given voltage, and charges the charging device.

7. The partial discharge measurement device according to claim 6, comprising a memory for storing a partial discharge signal processed by the arithmetic device, a wireless transmitter for transmitting the partial discharge signal stored in the memory, a wireless receiver which is installed at a location distant from the wireless transmitter and receives the signal from the wireless transmitter, a diagnostic device for performing defect determination from the signal received by the wireless receiver, and a switch for powering on or off the arithmetic device, the memory, and the wireless transmitter based on an instruction from the control unit.

8. The partial discharge measurement device according to claim 7, wherein the diagnostic device includes a partial discharge diagnostic unit for performing defect determination on the signal received by the wireless receiver, and a display unit for performing guidance display according to a result of diagnosis by the partial discharge diagnostic unit.

9. The partial discharge measurement device according to claim 8, wherein the guidance display on the display unit is color-coded in accordance with the result.

10. The partial discharge measurement device according to claim 1, wherein the frequency separation unit, the arithmetic device, the power supply device, and the control unit are formed in one and can be connected to the sensor with a single motion through a connection device.

11. A partial discharge measurement method comprising the steps of:
removing by a high-pass filter a commercial frequency component from a partial discharge signal which occurs in an apparatus under diagnosis and is detected by a sensor and extracting by a low-pass filter the commercial frequency component, thus separating the partial discharge signal into a partial discharge signal and a main circuit voltage phase signal;
receiving the separated partial discharge signal and the main circuit voltage phase signal and calculating by an arithmetic device a partial discharge signal synchronized with a main circuit voltage based on the partial discharge signal and the main circuit voltage phase signal;
extracting a voltage obtained by dividing the main circuit voltage of the commercial frequency from the low-pass filter and supplying a power supply voltage to the arithmetic device by a power supply device including a rectifier device, a charging device, and a DC/DC converter; and
issuing by a control unit an instruction for powering on or off at least the arithmetic device to the power supply device.

12. The partial discharge measurement method according to claim 11, wherein the voltage extracted by dividing the main circuit voltage of the commercial frequency from the low-pass filter is converted by the rectifier device into a DC voltage for charging the charging device, and upon receiving a monitor mode instruction from the control unit, the power supply device turns on the DC/DC converter and powers on the arithmetic device to start partial discharge measurement.

13. The partial discharge measurement method according to claim 11, comprising the steps of:
detecting by a detector circuit, at given time intervals, only a maximum value and a minimum value of a partial discharge signal that has passed through the high-pass filter;
performing A/D conversion, by an A/D converter, on a signal detected by the detector circuit;
time-synchronizing by a signal processing device the A/D converted signal with voltage phase information;
adjusting by a phase adjustment circuit a phase shift of a partial discharge signal that has passed through the low-pass filter;
detecting, by a waveform adjustment circuit, zero crossing of a signal whose phase shift has been adjusted by the phase adjustment circuit and sending only a zero cross signal to the signal processing device;
storing in a capacitor a voltage rectified by the rectifier device; and
charging the charging device by a second DC/DC converter which turns on if the voltage stored by the capacitor exceeds a given voltage.

14. The partial discharge measurement method according to claim 13, comprising the steps of:
storing in a memory a partial discharge signal processed by the arithmetic device;
transmitting by a wireless transmitter the partial discharge signal stored in the memory;
receiving, by a wireless receiver installed at a location distant from the wireless transmitter, the signal from the wireless transmitter;
performing defect determination by a diagnostic device from the signal received by the wireless receiver; and
powering on or off by a switch the arithmetic device, the memory, and the wireless transmitter based on an instruction from the control unit.

15. The partial discharge measurement method according to claim 14, comprising the steps of:
performing defect determination, by a partial discharge diagnostic unit, on the signal received by the wireless receiver; and
performing guidance display color-coded according to a result of diagnosis by the partial discharge diagnostic unit, on a display unit.
